(19) United States
(12) Patent Application Publication
(10) Pub. No.: US 2026/0150616 A1
(43) Pub. Date: May 28, 2026

(54) SEMICONDUCTOR PROCESS MONITORING AND WAFER INSPECTION

(71) Applicant: Hinalea Imaging Corp., Emeryville, CA (US)

(72) Inventors: Alexandre Fong, Orlando, FL (US); Guocai Shu, Pleasanton, CA (US); Matthew Eding, Cambridge (GB)

(21) Appl. No.: 19/265,866

(22) Filed: Jul. 10, 2025

Related U.S. Application Data
(60) Provisional application No. 63/670,635, filed on Jul. 12, 2024.

(51) Int. Cl. H10P 72/00; H10P 74/20

(52) U.S. Cl. CPC H10P 72/0604; H10P 74/203

(57) ABSTRACT

A system includes a semiconductor process interface and a processor. The processor is configured to initiate etalon free run motion; initiate free run image frame capture via the semiconductor process interface; determine whether a full set of band passes has been captured; and, in response to the full set of band passes having been captured, remove gaps not on spectrum reconstruction list and construct a data cube using data from gaps not removed. The system further includes a memory coupled to the processor and configured to provide the processor with instructions.

### CROSS REFERENCE TO OTHER APPLICATIONS

This application claims priority to U.S. Provisional Patent Application No. 63/670,635 entitled SYSTEM FOR SEMICONDUCTOR PROCESS MONITORING AND WAFER INSPECTION filed Jul. 12, 2024 which is incorporated herein by reference for all purposes.

### BACKGROUND OF THE INVENTION

Metrology and inspection are important for the management of the semiconductor manufacturing process. There are 400 to 600 steps in the overall manufacturing process of semiconductor wafers, which are undertaken during one to two months. If any defects occur early in the process, all the work undertaken in the subsequent time-consuming steps will be wasted. Contamination of devices such as semiconductors and disk drive components pose a serious risk for reduced yield and reliability resulting in billions of dollars of lost revenue every year. For instance, a particle on the surface of a wafer being exposed during a photolithography operation will create a shadow that prints in a subsequent step. If that particle is larger than half of the feature size of the process (Critical Dimension—CD), the die with the particle on its surface will likely be non-functioning. In photolithography, one particle may destroy the entire component, but in other steps perhaps one particle might destroy a component roughly 25% of the time. So, metrology and inspection processes are performed at critical points of the semiconductor manufacturing process to ensure that a certain yield can be confirmed and maintained.

### BRIEF DESCRIPTION OF THE DRAWINGS

Various embodiments of the invention are disclosed in the following detailed description and the accompanying drawings.

FIG. 1A is a diagram illustrating an embodiment of a system for semiconductor process monitoring.

FIG. 1B is a diagram illustrating an embodiment of a system for semiconductor wafer inspection.

FIG. 1C is a diagram illustrating an embodiment of a system for semiconductor process monitoring and wafer inspection.

FIG. 2 is a diagram illustrating an embodiment of a system for hyperspectral imager.

FIG. 3 is a diagram illustrating an embodiment of a Fabry-Perot etalon of a system for hyperspectral imaging.

FIG. 4A is a flow diagram illustrating an embodiment of a process for a system for hyperspectral imaging.

FIG. 4B is a flow diagram illustrating an embodiment of a process for a system for hyperspectral imaging.

FIG. 5 is a flow diagram illustrating an embodiment of a process for indicating to drive an etalon free running motion.

FIG. 6 is a flow diagram illustrating an embodiment of a process for determining a look up table.

FIG. 7A is diagram illustrating an embodiment of an object with an overlay.

FIG. 7B is a diagram illustrating an embodiment of spectra.

FIG. 7C is a diagram illustrating an embodiment of etching.

FIG. 7D is a diagram illustrating an embodiment of spectra.

FIG. 8 is a diagram illustrating an embodiment of a system for making a calibration measurement for a hyperspectral imaging system.

FIG. 9 is a flow diagram illustrating a process for calibrating a hyperspectral imager.

FIG. 10 is a flow diagram illustrating an embodiment of a process for calibrating an etalon.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A hyperspectral system is disclosed. The system comprises a processor and a memory. The processor is configured to initiate etalon free run motion, initiate free run image frame capture, determine whether a full set of band passes has been captured, and remove gaps not on spectrum reconstruction list and construct a data cube using data from gaps not removed in response to the full set of band passes having been captured. The memory is coupled to the processor and configure to provide the processor with instructions.

In some embodiments, the current state of the art of systems for semiconductor process monitoring and wafer inspection involve a variety of instruments including high resolution industrial cameras, precision spectrometers, optical profilometers, and laser interferometers at different process stages. Hyperspectral imaging introduces the potential to consolidate many of these instruments into a single multi-purpose tool that performs many of the metrology tasks in the process.

In some embodiments, the development of multi and hyperspectral imaging technologies have introduced new possibilities in optical based detection and identification. However, technologies such as push-broom grating, and acousto-optic tunable filters (AOTFs) have been limited in their ability to capture the data in a timely manner with the required spectral resolution and spatial uniformity and resolution. For example, push-broom gratings systems have been limited to applications where either the subject is either stationary or moving relatively slowly in a uniform vector. The protracted image acquisition times on the time scale of several seconds to minutes have made it impractical for use in high-speed production processes or for monitoring stochastic and dynamic processes common in semiconductor fabrication. Multi-spectral systems based on mosaiced band filters offer the acquisition rates for large fields of view, but the number of bands is limited and cannot be changed dynamically and are often lower spectral resolution. In addition, for either technology, one must tradeoff between spatial in spectral resolution for many of these technologies.

An integrated, self-contained system for rapid metrology of semiconductor processes and materials is disclosed. The system comprises a hyperspectral imager, fore optics, a processor, and custom software utilizing one or more deep machine learning algorithms. In various embodiments, the system is integrated into automated handling systems, scanning, analysis, and metrology. In some embodiments, the system is integrated into a distributed computing and communications environment.

The system addresses limitations of other hyperspectral technologies utilized in terms of spectral response range, speed of acquisition, and spectral and spatial resolution. This is accomplished by 1) having a spectral response range in the DUV (200 nm to 400 nm) and implementing a calibration system that omits gaps in order to enable reconstruction for DUV signals; and 2) employing free running and area/full frame image acquisition schemes to enable imaging of features critical to monitoring and evaluating semiconductor processes and materials. In this approach, the Fabry-Perot etalon is continuously varied by the computer and in parallel continuous single frame exposures of multiple band intensity images are captured by the sensor.

In some embodiments, the system utilizes front-staring imaging comprising a Fabry-Perot etalon, a broadband illumination system, an imaging area sensor, a set of focusing optics, a sample fixture, and a data acquisition and processing computer platform. In some embodiments, the system utilizes translation stages (e.g., a computer-controlled scanning motorized stage, a piezo-actuated stage, etc.). In some embodiments, the system utilizes one or more optics that provide a different field of view and/or magnification.

In some embodiments, the system can be integrated into an existing production line process via Semiconductor Equipment and Materials International Equipment Data Acquisition (SEMI EDA) SEMI Equipment Communications Standard/Generic Equipment Model (SECS/GEM) compliant and other possible interfaces and standard protocols such TTL synchronization triggers, Generic Interface for Cameras (GenICam), and industrial programmable logic controller (PLC) commands.

In some embodiments, the system includes a Fabry-Perot variable etalon based hyperspectral imaging system with its multi-band pass modes of operation improves performance and flexibility in terms of rapid full frame or area image acquisition, dynamically adjustable band selection, and high spatial and spectral resolution. The system addresses limitations of other hyperspectral systems in terms of spectral response range, speed of acquisition, while preserving spectral and spatial resolution. This is achieved using a free running frame image acquisition scheme that enables identification of features for rapidly changing scenes (e.g., stemming from fast-moving objects or dynamic phenomena). In this approach, the Fabry-Perot etalon is also varied in a free run fashion by the computer (e.g., a continuous sequence of positions, continuous motion, or resonant motion) while the free running frames are captured for multiple spectral bands. This approach enables a rapid spectral scanning system unconstrained by time delays associated with the stopping of the etalon mirror motion during frame acquisition.

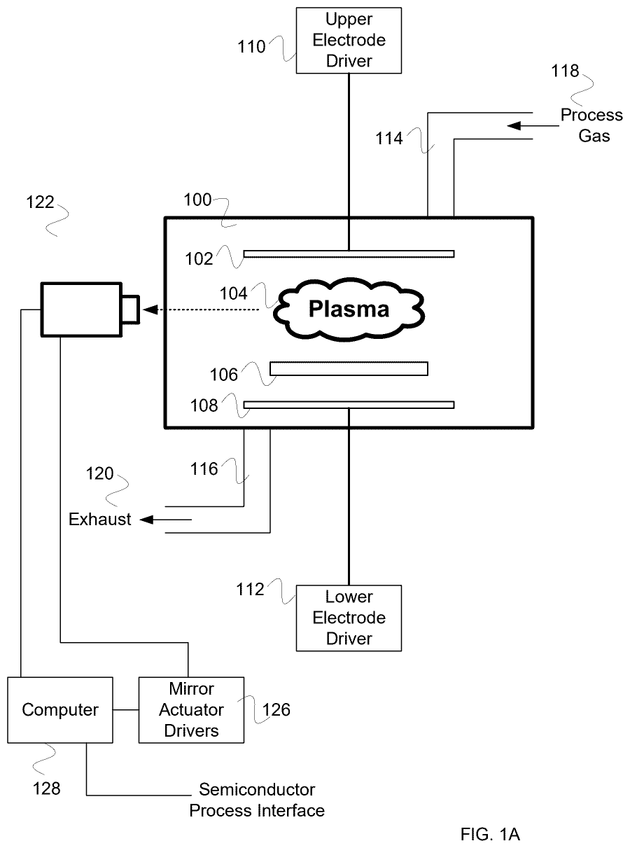

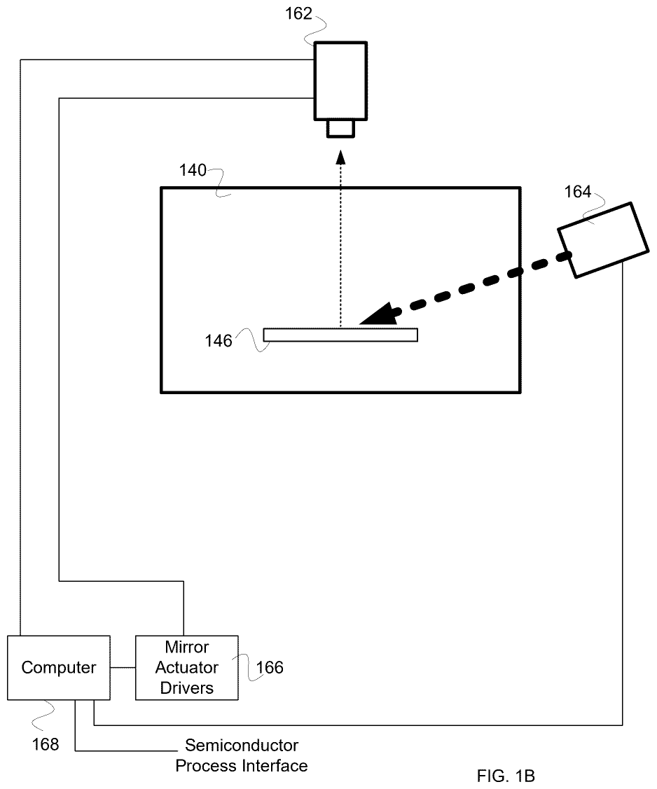

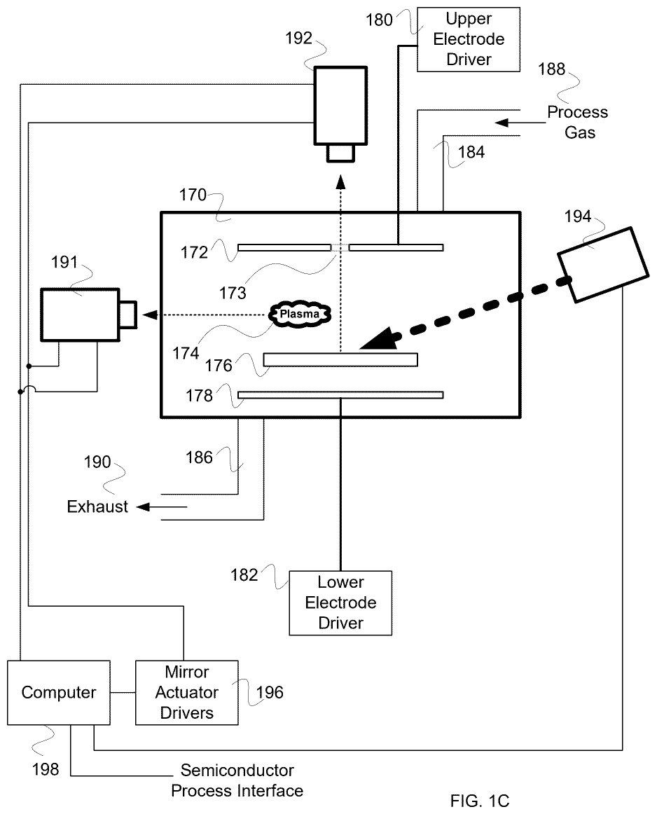

FIG. 1A is a diagram illustrating an embodiment of a system for semiconductor process monitoring. In the example shown, sample 106 (e.g., a silicon wafer) processed by plasma etching and monitored using hyperspectral imaging system 122. Sample 106 is processed in plasma etching device 100. Plasma etching device 100 includes upper electrode 102 driven by upper electrode driver 110 and lower electrode 108 driven by lower electrode driver 112 that creates charged gas plasma 104. Plasma etching device 100 has gas inlet 114 enabling process gas 118 to enter and exhaust outlet 116 enabling exhaust 120 to exit. Computer 128 indicates to hyperspectral imaging system 122 to acquire data and receives data from hyperspectral imaging system 122. In some embodiments, computer 128 receives an indication to acquire data via a semiconductor process interface (e.g., a computer interface between computer 128 and a computer controlling a semiconductor fabrication process). Computer 128 indicates positions to mirrors of an etalon (e.g., by providing drive voltages to piezos) using mirror actuator drivers 126. For the etch monitoring process, hyperspectral imaging system 122 of acquires the optical radiation emitted by the plasma. In some embodiments, hyperspectral imaging system 122 views charged gas plasma 104 from above so its view angle is normal to the plane of sample 106.

FIG. 1B is a diagram illustrating an embodiment of a system for semiconductor wafer inspection. In the example shown, sample 146 (e.g., a silicon wafer) is illuminated using illuminator 164 and monitored using hyperspectral imaging system 162. Sample 146 is inspected in semiconductor processing device 140 (e.g., a plasma etcher, a photolithography system, a deposition system, etc.). Computer 178 indicates to hyperspectral imaging system 162 to acquire data and receives data from hyperspectral imaging system 162. In some embodiments, computer 178 receives an indication to acquire data via a semiconductor process interface (e.g., a computer interface between computer 178 and a computer controlling a semiconductor fabrication process). Computer 178 indicates positions to mirrors of an etalon (e.g., by providing drive voltages to piezos) using mirror actuator drivers 176. Computer 178 indicates to illuminator 164 to illuminate sample 146 for the inspection process. In some embodiments, illuminator 164 illuminates sample 146 from above. In some embodiments, illuminator 164 provides illumination that is along the same axis as hyperspectral imaging system 162 (e.g., a beam combiner such as a beam splitter is used to inject the illumination along the same optic path as the imaging system).

FIG. 1C is a diagram illustrating an embodiment of a system for semiconductor process monitoring and wafer inspection. In the example shown, sample 176 (e.g., a silicon wafer) is illuminated using illuminator 194 and monitored using hyperspectral imaging system 192. Sample 176 is processed in plasma etching device 170. Plasma etching device 170 includes upper electrode 172 driven by upper electrode driver 180 and lower electrode 178 driven by lower electrode driver 182 that creates charged gas plasma 174. Plasma etching device 170 has gas inlet 184 enabling process gas 188 to enter and exhaust outlet 186 enabling exhaust 190 to exit. Computer 198 indicates to hyperspectral imaging device 192 and hyperspectral imaging device 191 to acquire data and receives data from hyperspectral imaging device 192 and hyperspectral imaging device 191. In some embodiments, computer 198 receives an indication to acquire data via a semiconductor process interface (e.g., a computer interface between computer 198 and a computer controlling a semiconductor fabrication process). Computer 198 indicates positions to mirrors of both etalons (e.g., by providing drive voltages to piezos) using mirror actuator drivers 196. Computer 198 indicates to illuminator 194 to illuminate sample 176 for the inspection process. For the etch monitoring process, the hyperspectral imaging system 191 acquires the optical radiation emitted by the plasma. For the wafer inspection (at different times from the etch monitoring), hyperspectral imaging system 192 views sample 176 through aperture 173 in upper electrode 172 from above so its view angle is normal to the plane of sample 176.

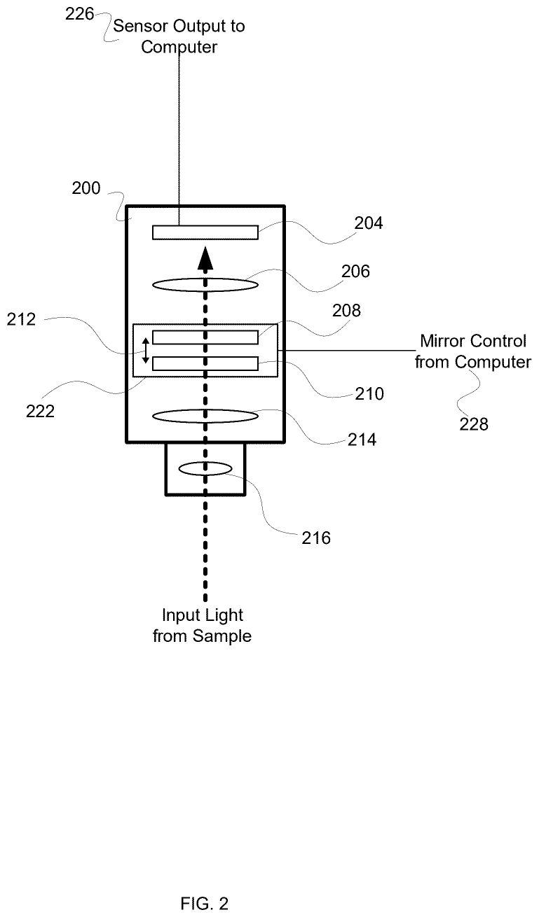

FIG. 2 is a diagram illustrating an embodiment of a system for hyperspectral imager. In some embodiments, hyperspectral imager 200 is used to implement hyperspectral imaging system 122 of FIG. 1A, hyperspectral imaging system 162 of FIG. 1B, and/or hyperspectral imaging system 191 and/or hyperspectral imaging system 192 of FIG. 1C. In the example shown, the system utilizes front-staring imaging comprising a Fabry-Perot etalon, an imaging area sensor, and a set of focusing optics. A light from the illuminated sample projects an image via the focusing optics through the Fabry-Perot etalon which modulates its mirror separation distance to enable the sensing of filtered light from the sample on the imaging area sensor in the inspection process. For the etch monitoring process, the imager acquires the optical radiation emitted by plasma. For example, a wafer sample or the plasma is positioned in field of view of hyperspectral imager 200. The field of view comprises a desired sampling area which can include an entire sample or an area of interest of the sample or a volume with charged plasma gas. All materials in the optical path (i.e., illumination sources, windows, lenses, filters, coatings and sensors) must be transmissive and/or responsive for the UV-visible spectral range applicable to the application (i.e., ˜200 nm to 800 nm) to the extent possible. In some embodiments, the system utilizes translation stages (e.g., a computer-controlled scanning motorized stage, a piezo-actuated stage, etc.). An operator can initiate the image/data capture via a user interface of a computer (e.g., computer 128 of FIG. 1A, computer 168 of FIG. 1B, or computer 198 of FIG. 1C). After the user initiates image/data capture, the computer indicates to illuminator to illuminate the sample and to hyperspectral imager 200 to take data while a mirror actuator driver as instructed by the computer (via mirror control from computer 228) moves Fabry-Perot etalon 222 to different gaps 212 between mirror 208 and mirror 210. In various embodiments, the ultraviolet (UV) system has about a few tens to hundreds or so bands (e.g., 10, 20, 30, 40, 50, 60, 70, 80, 90, 100, 200, 300, 400, 500, 600 bands) or between N and M bands (e.g., between N=10 and M=200 bands) using about a few hundred gaps (e.g., 100, 150, 200, 250, 277, 300, 350, 400, 450,500, 550, 600 gaps) or between K and L gaps (e.g., K=100 and L=300). The gap spacings are in the tens to hundreds of nm. For the UV system, Fabry-Perot etalon 222 is coated for transmission in the UV band of light. For the wafer inspection application, wideband illumination from an illuminator is reflected off the sample and light reflected within the field of view travels on a path towards sensor array 204 (e.g., a CMOS sensor, a CCD sensor, another solid-state imaging area sensor, or any other type of appropriate area sensor). For the etch monitoring process, the sensor acquires the optical radiation emitted by extended volume and area of the plasma. Sensor output to computer 226 carries data from sensor 204 to the computer.

In some embodiments, an RGB or Bayer pattern filter color or multi-channel sensor is used to collect multiple band-passes with responsiveness in the UV (200 to 400 nm) or beyond to generate a hyperspectral data cube, whereby each exposed frame in the series represents the image at a single or overlapping band-pass within a given filter wavelength band channel in order to facilitate and expedite the data-cube reconstruction process.

In some embodiments, a monochrome sensor is utilized.

In some embodiments, the path enters hyperspectral imager 200 via objective 216, passes through relay lens 214 is filtered by Fabry-Perot etalon 222 before passing through relay lens 206 to sensor array 204. In some embodiments, the system utilizes one or more optics that provide a different field of view and/or magnification (e.g., multiple objectives for objective 216). A computer controls image data taking over a series of gap positions and stores sensor 204 data. The raw data from sensor 204 is analyzed by the computer to generate hyperspectral data-cubes. Analysis of the raw data includes applying a calibration using a mathematical matrix transform to the data in the frames of images from sensor 204 to construct a data cube. Machine learning algorithms that have been trained on known samples are then applied to the reconstructed data cube to group or classify or perform metrology on regions of the image of interest. Training samples for the machine learning algorithms are comprised of a sufficiently large population of specimens, materials or subjects with and without an attribute, component or characteristic of interest. The performance of the model is statistically validated by testing against a smaller proportion of other samples to assess its ability to identify or measure that attribute, component or characteristic of interest. In practical use, this is often manifested as false color overlay or numerical output in the case of metrology applications. A number of algorithms or machine learning models can be utilized for this purpose. In some embodiments, there is a pre-processing of the data to remove noise, to segment or augment data, to mathematically transform, or to otherwise modify data prior to the application of such models. In some embodiments, a composite image is generated with markers or flags indicating their presence and displayed to a user via the computer.

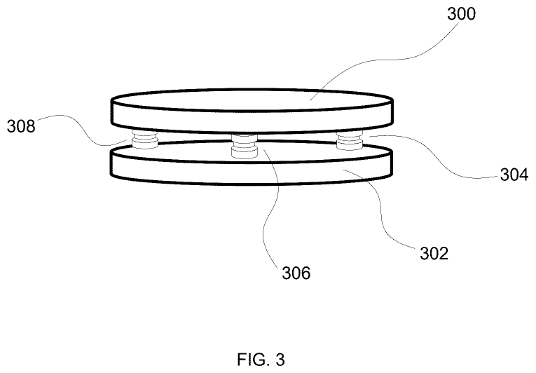

FIG. 3 is a diagram illustrating an embodiment of a Fabry-Perot etalon of a system for hyperspectral imaging. In some embodiments, Fabry-Perot etalon shown in FIG. 3 comprises mirror 208 and mirror 210 of Fabry-Perot 222 of FIG. 2. In the example shown, mirror 300 and mirror 302 can be positioned relative to each other to create an adjustable gap between mirror 300 and mirror 302 using piezo actuator 304, piezo actuator 306, and piezo actuator 308. In some embodiments, piezo actuator 304, piezo actuator 306, and piezo actuator 308 have their length adjusted by applying a voltage across the piezo material. In order to keep mirror 300 and mirror 302 parallel to each other (e.g., the plane of mirror 300 is parallel to the plane of mirror 302), drive voltages to piezo actuator 304, piezo actuator 306, and piezo actuator 308 must be calibrated for each desired gap distance. For example, mirror 300 and mirror 302 are illuminated using a uniform flat laser beam across the full mirror faces and the laser beam that is transmitted through the etalon of the two mirrors is imaged onto a sensor. The flatness can be measured using the uniformity of the transmitted light. Once the drive voltages (e.g., for the static situation) have been determined for each gap, the drive voltages for each gap are stored in a look up table (e.g., gap index number (e.g., associated with gap of x nm), voltage for piezo 1 (e.g., piezo 304), voltage for piezo 2 (e.g., piezo 306), and voltage for piezo 3 (e.g., piezo 308)). In some embodiments, in order to achieve the free running motion for the mirrors an offset drive voltage for each gap position for each piezo is needed for the moving piezo to be in the correct position at the next time interval, so that when setting a next target position using the voltage for each piezo an offset (e.g., an offset stored for each gap for each piezo) is included in the drive voltage (e.g., gap index voltage for piezo 1 plus offset voltage for piezo 1, gap index voltage for piezo 2 plus offset voltage for piezo 2, and gap index voltage for piezo 3 plus offset voltage for piezo 3). In some embodiments, these offset values for each gap are stored in the look up table (e.g., gap index number (e.g., associated with gap of x nm), voltage for piezo 1, offset voltage for piezo 1, voltage for piezo 2, offset voltage for piezo2, and voltage for piezo 3, and offset voltage for piezo 3).

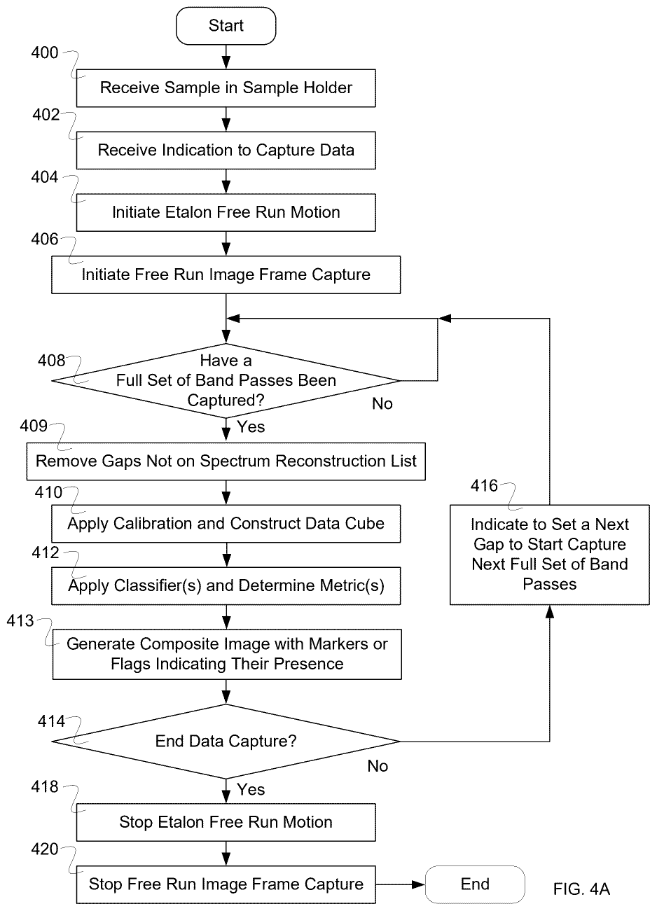

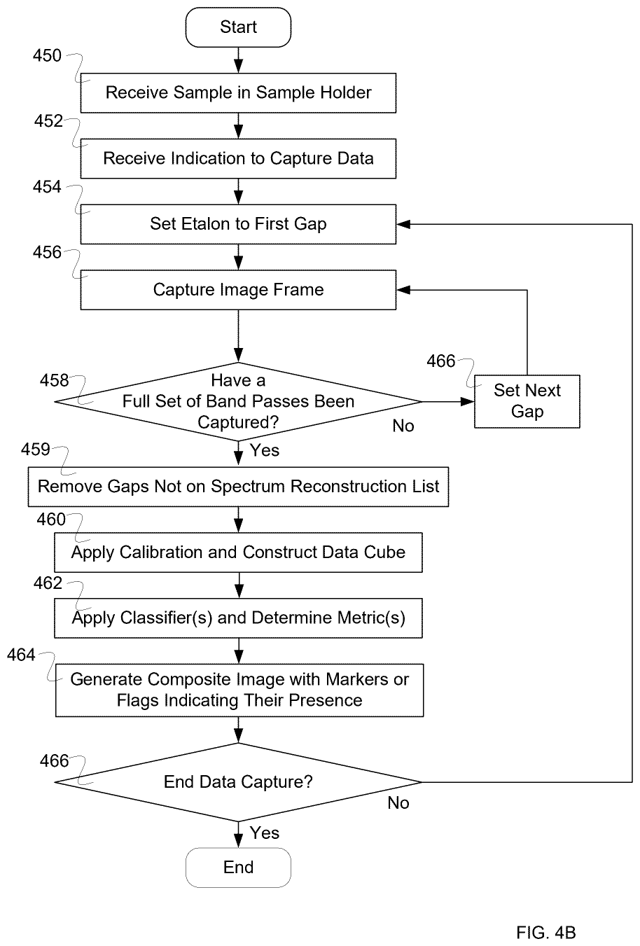

FIG. 4A is a flow diagram illustrating an embodiment of a process for a system for hyperspectral imaging. In some embodiments, the process of FIG. 4A is implemented using the system of FIG. 1A, FIG. 1B, and/or FIG. 1C. In the example shown, in 400 a sample is received in a sample holder. For example, a sample is placed in the field of view where the imaging system objective lens is normal to the sample plane, and its field of view matches the area of interest. In some embodiments, a set of objective lenses are employed to capture the area or region of interest at the required spatial resolution. In some embodiments, the selected objective lens has a field of view that matches a desired sampling area. In some embodiments, the position of the sample can be adjusted using one or more sample positioners to manipulate the relative position of the sample and the system for hyperspectral imaging (e.g., moving the sample in the x, y, or z directions where x, y are perpendicular to the imaging axis of the hyperspectral imaging system (e.g., in the plane of the sample) and z is along the axis of the hyperspectral imaging system (e.g., normal to the plane of the sample). In some embodiments, the one or more sample positioners are controlled from a computer. In 402, an indication is received to capture data. For example, the operator initiates the image and data capture via a user interface from a computer system. In 404, etalon free run motion is initiated. For example, the mirror separation distance in the Fabry-Perot etalon is continuously varied by the computer during an etch process, where the time is critically important. In 406, free run image frame capture is initiated. For example, the computer captures continuous single frame exposures of multiple band intensity by the sensor and the image frames are saved digitally on a storage medium. In some embodiments, the computer captures a frame at specified times - for example, a frame can be captured at a time in a look up table or based on a time-of-flight estimation of location (e.g., knowing the speed of the mirror motion and the time elapsed since the motion started). In some embodiments, the computer captures a frame at a specified gap position based on a measure of the gap (e.g., based on a sensor measure of the gap such as a capacitive sensor or a linear encoder). In 408, it is determined whether a full set of band passes have been captured. For example, the computer system determines whether the mirror has moved through the entire range of motion and frames are captured such that the full spectral range of interest is captured. In response to determining a full set of band passes have not been captured, control passes to 408. In some embodiments, the full set of band passes depends on the spectral range of the application. For a given spectral range, there is a maximum number of gap positions beyond which no additional information is gained (i.e., no more improvement in spectral resolution, range, or SNR). For the UV range, 200 to 400 nm this is ˜100 bands.

In response to determining a full set of band passes have been captured, control passes to 409. In 409, gaps are removed that are not on the spectrum reconstruction list. For example, a process is used to identify peaks, confirm the peaks at different gap positions, and then optimizing the selection of which gap in terms of transmission, location/isolation from other peaks and, for the case of the plasma etch process, ones that you can move to and from quickly (say between two bands of interest). In some embodiments, gaps are removed by setting gaps in the look up table to arrange the motion to skip undesired gap positions. In 410, calibration is applied and a data cube is constructed using data from gaps not removed. For example, a mathematical matrix transform is applied to the data in the frames of images from gaps not removed, either to each frame as acquired or to all frames at once at the end of the collection cycle, such that a calibration is applied, and a data cube is constructed (e.g., the calibrated data is organized and stored into a data structure). In some embodiments, the data cube, also known as a hypercube, is a three-dimensional representation of the captured data whereby the two dimensions of the image's spatial components (x, y coordinates) are augmented by the wavelength in the third dimension. In some embodiments, the number of band-passes required in each data cube varies depending upon the resolution of the spectral signature required to differentiate between sample components that need to be detected. For example, for closely similar samples, this can be typically hundreds of band-passes. Such data cubes can be very large files, typically 1 GB each. In 412, classifiers are applied, and metrics are determined. For example, machine learning algorithms that have been trained on known samples, which may include but are not restricted to bare wafers at different stages of the production process, singulated wafer chips and etched and partially packaged wafers near the end of the cycle. The machine learning algorithms are then applied to the data cube to group or classify regions of the image of interest to determine whether one or more of the following is present: contaminant(s), inclusion(s), irregularity(ies), non-uniformity(ies), and/or surface damage incurred during the etching and singulation processes and other components that would render an end product defective. In 413, a composite image is generated with markers or flags indicating their presence. For example, an image is displayed for a user using a computer. In 414, it is determined whether to end data capture. In response to determining not to end data capture, control passes to 416. In 416, it is indicated to set a next gap to start capturing a next full set of band passes, and control passes to 408. For example, the next gap is set to a first gap to be able to step through all the gaps, or gaps is set to a last gap, and gaps are able to be stepped through backwards. In response to determining to end data capture, control passes to 418. In 418, etalon free run motion is stopped. For example, the computer system indicates to a piezo actuator driver to stop motion. In 420, free run image frame capture is stopped, and the process ends.

FIG. 4B is a flow diagram illustrating an embodiment of a process for a system for hyperspectral imaging. In some embodiments, the process of FIG. 4B is implemented using the system of FIG. 1A, FIG. 1B, and/or FIG. 1C. In the example shown, in 450 a sample is received in a sample holder. For example, a sample is placed in the field of view where the imaging system objective lens is normal to the sample plane, and its field of view matches the area of interest. In some embodiments, a set of objective lenses are employed to capture the area or region of interest at the required spatial resolution. In some embodiments, the selected objective lens has a field of view that matches a desired sampling area. In some embodiments, the position of the sample can be adjusted using one or more sample positioners to manipulate the relative position of the sample and the system for hyperspectral imaging (e.g., moving the sample in the x, y, or z directions where x, y are perpendicular to the imaging axis of the hyperspectral imaging system(e.g., in the plane of the sample) and z is along the axis of the hyperspectral imaging system (e.g., normal to the plane of the sample). In some embodiments, the one or more sample positioners are controlled from a computer. In 452, an indication is received to capture data. For example, the operator initiates the image and data capture via a user interface from a computer system. In 454, etalon is set to a first gap. For example, the mirror separation distance in the Fabry-Perot etalon is set by the computer during a wafer inspection process to a first gap position. In 456, an image frame is captured. For example, the computer captures a frame of multiple bands of intensity filtered by the etalon using the sensor and the image frames are saved digitally on a storage medium. In 458, it is determined whether a full set of band passes have been captured. For example, the computer system determines whether the mirror has moved through the entire range of motion and frames are captured such that the full spectral range of interest is captured. In response to determining a full set of band passes have not been captured, control passes to 466. In 466, a next gap is set. For example, the etalon gap is controlled using the computer to set a new gap position via actuator drivers (e.g., a set of piezo drivers). In response to determining a full set of band passes have been captured, control passes to 459. In 459, gaps are removed that are not on the spectrum reconstruction list. For example, a process is used to identify peaks, confirm the peaks at different gap positions, and then optimizing the selection of which gap in terms of transmission, location/isolation from other peaks and, for the case of the plasma etch process, ones that you can move to and from quickly (say between two bands of interest). In some embodiments, gaps are removed by setting gaps in the look up table to arrange the motion to skip undesired gap positions. In 460, calibration is applied and a data cube is constructed using data from gaps not removed. For example, a mathematical matrix transform is applied to the data in the frames of images from gaps not removed, either to each frame as acquired or to all frames at once at the end of the collection cycle, such that a calibration is applied, and a data cube is constructed (e.g., the calibrated data is organized and stored into a data structure). In some embodiments, the data cube, also known as a hypercube, is a three-dimensional representation of the captured data whereby the two dimensions of the image's spatial components (x, y coordinates) are augmented by the wavelength in the third dimension. In some embodiments, the number of band-passes required in each data cube varies depending upon the resolution of the spectral signature required to differentiate between sample components that need to be detected. For example, for closely similar samples, this can be typically hundreds of band-passes. Such data cubes can be very large files, typically 1 GB each. In 462, classifiers are applied, and metrics are determined. For example, machine learning algorithms that have been trained on known samples, which may include but are not restricted to bare wafers at different stages of the production process, singulated wafer chips and etched and partially packaged wafers near the end of the cycle. The machine learning algorithms are then applied to the data cube to group or classify regions of the image of interest to determine whether one or more of the following is present: contaminant(s), inclusion(s), irregularity(ies), non-uniformity(ies), and/or surface damage incurred during the etching and singulation processes and other components that would render an end product defective. In some embodiments, a key metric being determined is end point detection (EPD). EPD is the stage in the process where the plasma spectra has reached a desired state over time indicating the etching is complete and can halt.

In 464, a composite image is generated with markers or flags indicating their presence. For example, an image is displayed for a user using a computer. In 466, it is determined whether to end data capture. In response to determining not to end data capture, control passes to 454. In response to determining to end data capture, the process ends.

The data cube is analyzed using a combination of one or more supervised machine learning clustering, classification, and regression algorithms (e.g., principal component analysis, K-Means, spectral angle mapping that is first trained on sample data cubes of components, or any other appropriate algorithm).

In some embodiments, principal component analysis (PCA) is used to simplify complexity in high-dimensional data while retaining trends and patterns by transforming data into fewer dimensions to summarize features.

In some embodiments, K-Means is an iterative clustering algorithm used to classify data into a specified number of groups by beginning with an initial set of randomly determined cluster centers. Each pixel in the image is then assigned to the nearest cluster center by distance and each cluster center is then recomputed as the centroid of all pixels assigned to the cluster. This process repeats until a desired threshold is achieved.

In some embodiments, spectral angle mapping (SAM) compares a given spectra to a known spectrum, treating both as vectors and calculating the “spectral angle” between them and grouping them with respect to a threshold based on that angle.

In various embodiments, classification is based on morphology (i.e., shape) and/or intensity images (i.e., distribution of brightness). In various embodiments, classification utilizes a hybrid deep-learning framework, long-short term memory (LSTM) network, deep residual network (ResNet), and/or one-dimensional convolutional neural networks (1D-CNN).

Once trained, these algorithms can be used to recognize, identify, and mathematically group spectral and spatial characteristics associated with specific characteristics of interest in a sample. Such characteristics include, for example, spectral profiles, spectral signatures, the shape and size of the component, etc.

The above algorithms have demonstrated the ability to distinguish a variety of components.

In some embodiments, one or more neural network models are used to detect, identify, and/or classify images—for example, a convolutional neural network (CNN), a region-based convolutional neural network (R-CNN), a Fast R-CNN model, a Faster R-CNN model, a You Only Look Once (YOLO) model from the family of YOLO models, or any other appropriate neural network model.

In various embodiments, a bounding box model is used to localize and/or detect images of potential components. In various embodiments, the bounding box model comprises one or more of a Tensor Flow model (e.g., a Tensor Flow application programming interface (API)), a convolutional neural network, a region-based convolutional neural network (R-CNN), a Fast R-CNN model, a Faster R-CNN model, a You Only Look Once (YOLO) model from the family of YOLO models, an EdgeBoxes model, or any other appropriate bounding box model.

In some embodiments, the bounding box model is trained using the intersection over union (IoU) method (i.e., the intersection of the computed bounding box with the bounding box for ground truth) with the IoU value set to an appropriate value corresponding to true positives, false positives, and false negatives (e.g., the IoU value is set to 0.5, 0.75, 0.9, 0.95, or any appropriate value). An IoU value of 1 implies that the predicted and the ground-truth bounding boxes perfectly overlap. For example, using an IoU value of ≥0.5, the object detection is classified as a true positive (TP). If the IoU value is <0.5, then the object detection is classified as a false positive (FP). If the ground truth is present in the image and the model failed to detect the object, the object detection is classified as a false negative (FN). A true negative (TN) occurs for every part of the image where an object was not predicted; however, since this is not useful for object detection, TN is ignored for the purpose of measuring model performance during training.

In some embodiments, precision and recall values are calculated and plotted (e.g., as precision and recall or ‘PR graphs’) to evaluate the performance of the bounding box model (e.g., calculated from the number of true positives (TP), false positives (FP), and false negatives (FN) achieved while training the bounding box model). For example, precision and recall are calculated using the formulas Precision=TP/(TP+FP) and Recall=TP/(TP+FN). In some embodiments, the performance of the bounding box model is evaluated using the mean average precision (mAP) value (e.g., using a multi-point interpolated average precision). In some embodiments, the point of operation for the performance of the bounding box model on the generated PR graphs is determined empirically from test data used during training the system (e.g., the bounding box model is set to operate at greater than 50%, 60%, 68%, 72%, 80%, or any other appropriate level of recall). In some embodiments, the point of operation for bounding box model on the generated PR graphs is adjusted after further model training and/or evaluation under operational conditions (e.g., to change the number of generated bounding boxes that require further evaluation).

In some embodiments, one or more neural network models are used to classify images of potential image components of interest. For example, the neural network model used to classify images of potential components, inclusions or defects (i.e., ‘the classifier model’) assigns a class label to the one or more possible components outlined by a bounding box. In some embodiments, the classifier model uses sharp edge detection. In some embodiments, the classifier model uses machine learning approaches. For example, the classifier model uses one or more neural network models to classify possible components that have been detected in the bounding box model. In various embodiments, the one or more neural network models used by the classifier model are the same, different, or a combination of same or different models as used by the bounding box model. In some embodiments, class labels comprise characteristics of the input image (e.g., texture, shape, or color aspects) that are summarized by numerical vectors (i.e., feature vectors).

In some embodiments, the one or more neural network models are trained using hierarchical feature learning (i.e., ‘layered learning’). For example, the first layers of the neural network model are trained to learn representations of basic (low-level) features, such as edges. Further down the network, layers output representations of more specific features, corresponding to parts of the object. After the last layer, the representations are high-level and allow a clear separation between different objects with the network having learned to distinguish among the different classes.

In some embodiments, the one or more neural network models are trained using hyperspectral data (e.g., hyperspectral data from potential components detected by a bounding box model). In some embodiments, one or more neural network models are trained to match the observed hyperspectral data with a library of hyperspectral data corresponding to known components. In some embodiments, the output of the one or more neural network models provides the class label of an identified image component (e.g., to a system user). In various embodiments, the provided class label of an identified component includes related metadata (e.g., time and date, a level of confidence, the number and/or density of the identified component, a plot or graph of the associated hyperspectral data, etc.).

In the disclosed system, a composite image is generated from the processed grouped data. In some embodiments, the composite image provides an indication of the presence of component (e.g., providing an immediately actionable indication). In some embodiments, a threshold based on statistical likelihood is applied to provide a binary answer or response (e.g., false color image presentation, “go/no go” flags or warnings, etc.).

In some embodiments, the system utilizes machine learning clustering algorithms trained on hyperspectral images of known component of interest.

In some embodiments, the algorithms utilize both component spectral and spatial (e.g., shape and size) characteristics in their training.

In various embodiments, wherein the component or features presented are sparsely distributed methods for anomaly detection and targeting at the pixel and sub-pixel scale based on statistical and machine learning algorithms are used to rapidly locate and identify individual cells. In various embodiments, high-speed targeting algorithms utilized in defense and remote sensing/surveillance applications are used to automate the targeting and identification of components in a sparsely populated field of view. For example, airborne remote-sensing signal processing techniques, machine-learning techniques for anomaly detection, and/or orthogonal projection techniques are used to improve the speed and accuracy of the classification algorithms.

In some embodiments, the UI will provide an option to allow the user to train the algorithm for a component of interest through a guided process (e.g., an application wizard).

In various embodiments, the instrument is integrated into an in-line inspection system wherein samples are collected for analysis.

In some embodiments, no accommodations need to be made for the Fabry-Perot etalon stopping, settling, or pausing and/or any coordination between the Fabry-Perot etalon motion and the triggering of acquisition of a sensor frame.

In some embodiments, it is critical for the mirrors in the Fabry-Perot etalon maintain parallelism to one another throughout the image acquisition process regardless of position or motion, the rate of transit of the moving mirror elements must be tuned to the mechanical specifics of a given device.

In some embodiments, this is accomplished through a feedback process where the maximum transit range segments and rates are set by a comparison of the resultant spectra with a known ground truth (i.e., spectrometer, monochromator, etc.).

In some embodiments, this feedback process is used to establish the mirror gap position indices required to derive the wavelength calibration for each multiple band pass mode of the etalon.

In some embodiments, the sensor exposure must be commensurate with its frame rate and mirror motion so as to acquire an intensity image for a stable established set of band passes at any given position. In some embodiments, the sensor exposure and etalon mirror motion are controlled and adjusted electronically via firmware and embedded micro-controller or processor.

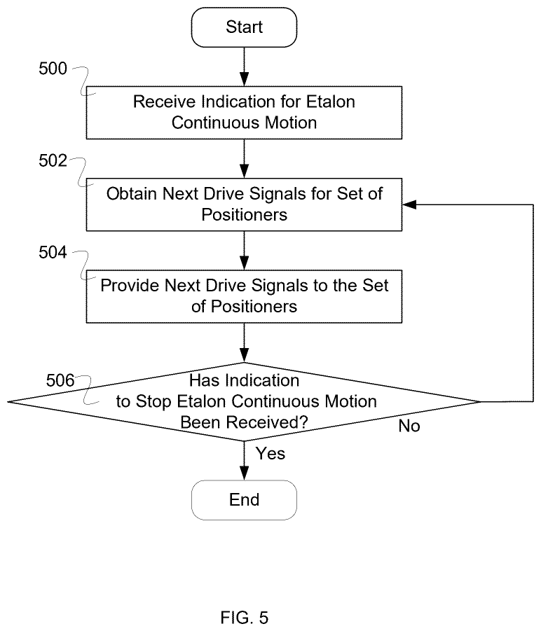

FIG. 5 is a flow diagram illustrating an embodiment of a process for indicating to drive an etalon free running motion. In some embodiments, the process of FIG. 4 is used to implement a process after 404 of FIG. 4. In the example shown, in 500 an indication is received for etalon free run motion. For example, a computer provides an indication that the etalon is to start or continue free run motion. In 502, a next drive signal is obtained for the set of positioners. For example, drive signals are obtained for the three piezo positioners for setting the gap between two etalon mirrors (e.g., a look up table is referenced related to a next desired position). In 504, the next drive signals are provided to a set of positioners. For example, the next drive signals are provided to an actuator driver to position the mirror positioners (e.g., three drive signal values are provided to position the mirrors in parallel to each other at a desired gap spacing). In 506, it is determined whether an indication has been received to stop free run motion. For example, the computer provides an indication to stop free run motion (e.g., after data for desired band passes has been collected). In response to determining that an indication has not been received to stop etalon free run motion, control passes to 502. In response to determining that an indication has been received to stop etalon free run motion.

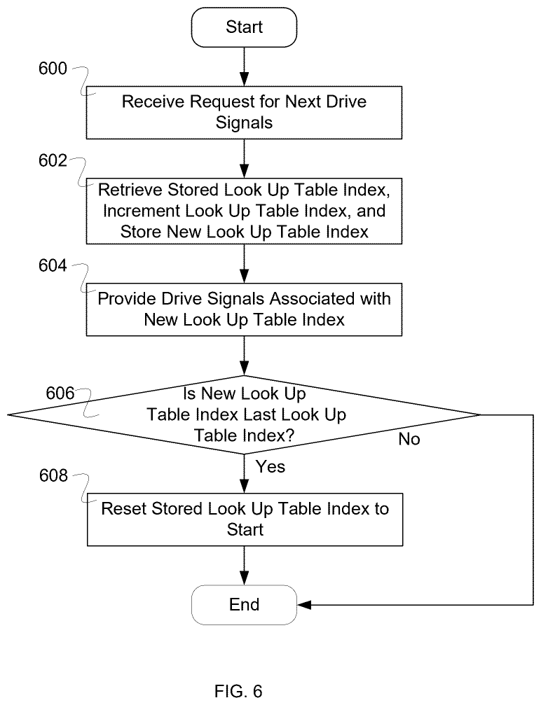

FIG. 6 is a flow diagram illustrating an embodiment of a process for determining a look up table. In some embodiments, the look up table determined in the process of FIG. 6 is used for indicating a position to a set of positioners in 502 of FIG. 5. In the example shown, in 600 a request is received for next drive signals. For example, during etalon free run motion, a set of drive signals is needed to position the mirrors in parallel at specific gap separations. In 602, a stored look up table index is retrieved, a look up table index is incremented, and the new look up table index is stored. For example, a last stored index is retrieved from memory, the last stored index value is incremented to make a new index value and this new index value is stored. In 604, drive signals associated with the new look up table index are provided. For example, using the new look up table index, the look up table is used to obtain drive signals (e.g., values for the positioners such as piezo actuators setting the gap separation between two etalon mirrors). In 606, it is determined whether the new look up table index is a last look up table index. For example, it is determined whether the index points to the end of the look up table. In response to the new look up table index not being a last look up table index, the process ends. For example, the look up table still has viable next entries for a next request. In response to the new look up table index being a last look up table index, control passes to 608. In 608, the stored look up table index is reset to start value (e.g., index is 0 so that when incremented in 602 the system loads the first gap value). For example, the stored look up table is set to the value prior to a first look up table entry so that when the look up table index is incremented on the next request, the look up table retrieves the first entry in the look up table.

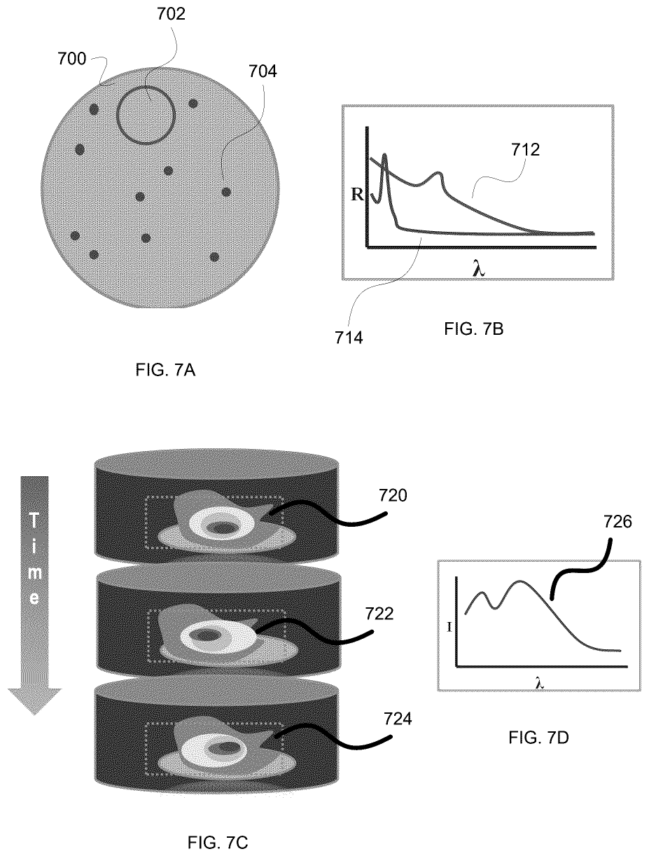

FIG. 7A is diagram illustrating an embodiment of an object with an overlay. In some embodiments, the image of a wafer with classifications of FIG. 7A is created using a hyperspectral imaging system of FIG. 1. In the example shown, a hyperspectral imager has been used to image wafer 700 and the data processed using a classifier. The data from hyperspectral imager is used to classify areas in an image of wafer 700 using spectral information. For example, circle area 702 has a different spectrum compared to dot 704. In some cases, circle area 702 has a spectrum corresponding to a wafer area with no defects, whereas dot 704 has a spectrum corresponding to a defect.

FIG. 7B is a diagram illustrating an embodiment of spectra. In some embodiments, the spectra of FIG. 7B correspond to classified locations of a wafer of FIG. 7A. In the example shown, spectra 712 corresponds to an area with no defects (e.g., circle area 702 of FIG. 7A), spectra 714 corresponds to a defect (e.g., dot 704 of FIG. 7).

FIG. 7C is a diagram illustrating an embodiment of etching. In some embodiments, the image of etching of a wafer with overlay of spectral measurement classifications of FIG. 7C is created using a hyperspectral imaging system of FIG. 1. In the example shown, a hyperspectral imager has been used to image etching of a wafer and the data processed using a classifier. The data from hyperspectral imager is used to classify areas and is displayed as a pseudo color image that varies over time (e.g., overlay 720, overlay 722, overlay 724, etc.) using spectral information. For example, overlay 720 has a different spatial pattern compared to overlay 722 and overlay 724. In some cases, different pseudo colors correspond to different characteristics as measured using a hyperspectral imager (e.g., different plasma composition).

FIG. 7D is a diagram illustrating an embodiment of spectra. In some embodiments, the spectra of FIG. 7d corresponds to a location within the plasma of FIG. 7C. In the example shown, spectra 726 corresponds to a location within the plasma. In some embodiments, the types of composite images generated by an application machine learning classifier false color overlays on the plasma indicate the stage in the deposition process.

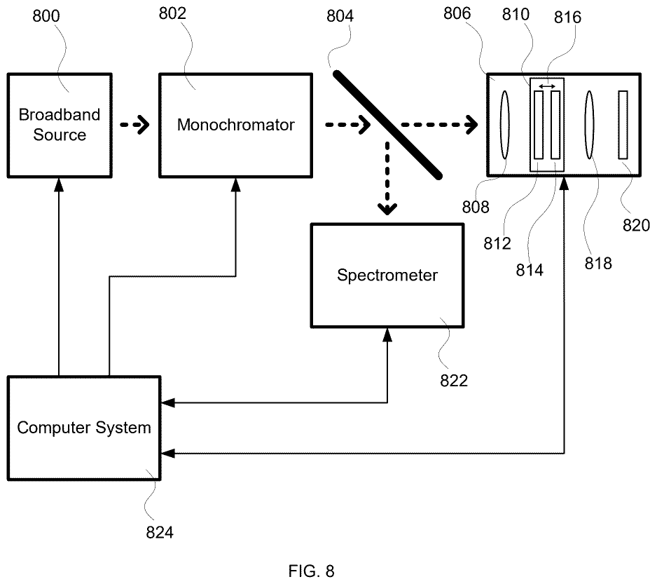

FIG. 8 is a diagram illustrating an embodiment of a system for making a calibration measurement for a hyperspectral imaging system. In some embodiments, FPI 200 of FIG. 2 is used to implement hyperspectral imager 806 of FIG. 8. In the example shown, broadband source 800 generates light that is passed through monochromator 802 to filter the light to a single wavelength of light. In some embodiments, broadband source 800 comprises two separate sources (e.g., a deuterium lamp and a quartz tungsten halogen lamp, each with respective regulated power supplies) and combined optically into a common output path into the monochromator. This single wavelength of light is split using beam splitter 804 to be measured by spectrometer 822 for a precise measurement of the wavelength and to illuminate hyperspectral imager 806. Hyperspectral imager 806 comprises relay lens 808, etalon 810 comprising mirror 812 and mirror 814 separated by gap 816, relay lens 818, and image sensor 820. In some embodiments, the measurement of the wavelength by spectrometer 822 is done sequentially without beam splitter 804 by disposing spectrometer 822 in the location of hyperspectral imager 806 after hyperspectral imager 806 measurement. A response of hyperspectral imager 806 can then be made for multiple gap spacings. A full calibration is time consuming as it requires setting monochromator 802 at a specific wavelength and then for that specific wavelength measuring a full set of gap spacings. This measurement is then repeated for another specific wavelength until a full set of wavelengths has each been measured at a full set of gap spacings.

In some embodiments, computer system 824 is used for controlling and/or coordinating the calibration measurement. For example, computer system 824 is able to indicate turning broadband source 800 on or off, indicate selecting a wavelength via monochromator 802, indicate setting a gap spacing for hyperspectral imager 806, indicate acquiring an image using image sensor 820, indicate measuring a wavelength or spectra using spectrometer 822, receive data from hyperspectral imager 806 (e.g., image data, gap data, etc.), from spectrometer 822 (e.g., wavelength or spectra data, etc.), from monochromator 802 (e.g., wavelength setting data, etc.), from broadband source 800 (e.g., on/off status, etc.), display an interface, receive commands, or any other appropriate function for computer system 824.

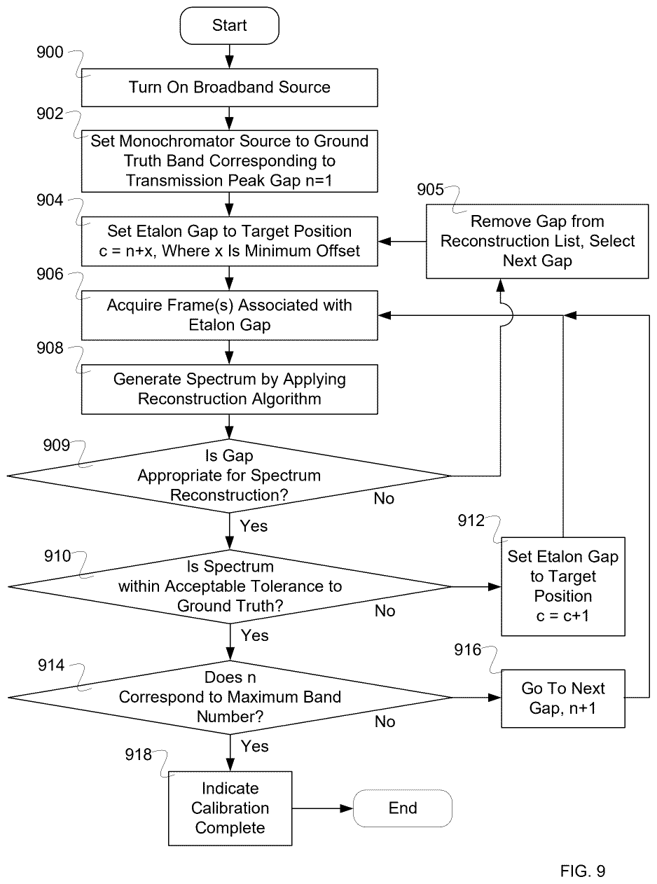

FIG. 9 is a flow diagram illustrating a process for calibrating a hyperspectral imager. In some embodiments, the process of FIG. 9 is used to calibrate hyperspectral imager 806 of FIG. 8. In the example shown, in 900 a broadband source is turned on. In 902, a monochromator source is set to ground truth band corresponding to transmission peak gap n=1. In 904, etalon gap is set to target position c=n+x, where x is minimum offset. In 906, one or more frames is/are acquired associated with the etalon gap. In 908, A spectrum is generated by applying a reconstruction algorithm. In 909, it is determined whether a gap is appropriate for spectrum reconstruction. For example, a process is used to identify peaks, confirm the peaks at different gap positions, and then optimizing the selection of which gap in terms of transmission, location/isolation from other peaks and, for the case of the plasma etch process, ones that you can move to and from quickly (say between two bands of interest). UV band specific gaps tend to be narrower which result in unique assembly and alignment differences compared to other spectral ranges. Criteria for acceptance and rejection of gaps include but are not restricted to maximizing peak transmission while maintaining as low a transmission floor as possible, trade-offs between narrow and wide resolution (FWHM), avoidance of intermediate peaks between target bands in order to ensure full and not cut-off peaks and bands with leakage. The total number of gaps omitted or dropped depends on spectral range interest, the above criteria, and application specifics. Typically, around 80% of gaps are excluded for semiconductor etch applications. In response to determining that the gap is not appropriate for spectrum reconstruction, control passes to 905. In 905, the gap is removed from a reconstruction list and a next gap is selected, and control passes to 904. In response to determining that the gap is appropriate for spectrum reconstruction, control passes to 910. In 910, it is determined whether the spectrum is within acceptable tolerance to the ground truth. In response to the spectrum not being within acceptable tolerance to ground truth, control passes to 912. In 912, the etalon gap is set to target position c=c+1 and control passes to 906. In response to the spectrum being within acceptable tolerance to ground truth, control passes to 914. In 914, it is determined whether n corresponds to a maximum band number. In response to n not corresponding to a maximum band number, control passes to 816. In 916, the system goes to the next gap, n+1, and control passes to 806. In response to n corresponding to a maximum band number, control passes to 918. In 918, it is indicated that calibration is complete, and the process ends.

In some embodiments, ‘n’ comprises an index representing a gap position for a wavelength band of interest for which the instrument is being calibrated to. For a 200-400 nm UV system, 200 nm would be the first band and “n”, say 1, would the gap where it would be found. In this free-run mode of operation where the mirror is made to move continuously, it turns out programming the driver to go to “n” doesn't yield the best spectrum. Telling it to overshoot by some distance “x” does. However, once it reaches “n” you move on to the next band/gap, say n2 by telling it to go to n2+x and so forth. Determining what “x” is, is the iterative process described above. The calibration process is complete once that offset “x” has been determined for all gaps/bands. These values are stored in the look up table (LUT) and applied at run-time.

In some embodiments, gaps to be omitted are determined prior to the x offsets being found—for example, the set of target gaps are defined and then the x offsets determined by the spectral quality test. In some embodiments, knowledge of the spectral peak of the ground truth source is used to set a criteria for how well the reconstructed peak from the acquired data matches it, and if the reconstructed peak is outside acceptable criteria, then that gap and the offset used are unacceptable.

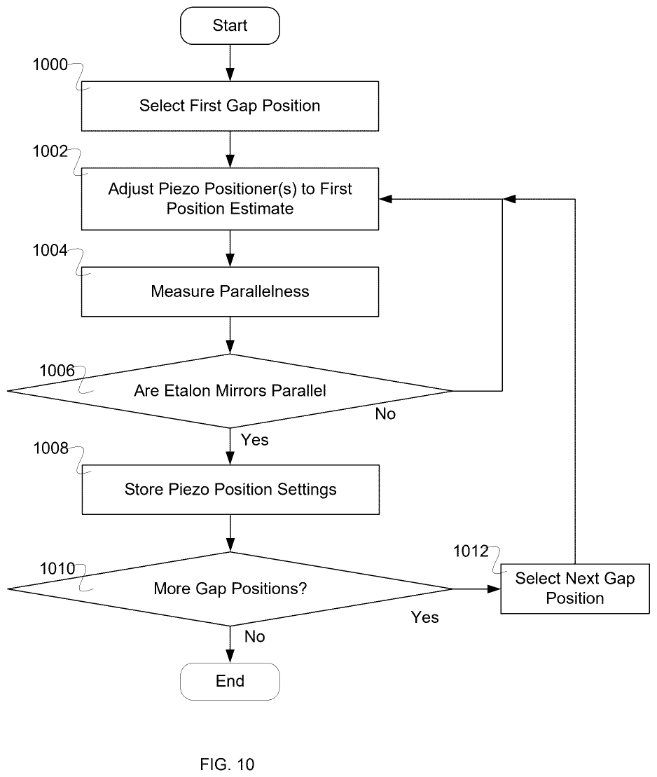

FIG. 10 is a flow diagram illustrating an embodiment of a process for calibrating an etalon. In some embodiments, the gap positions being calibrated are for an etalon of a hyperspectral imager (e.g., hyperspectral imager 122 of FIG. 1). In the example shown, in 1000 a first gap position is selected. In 1002, piezo positioner(s) is/are adjusted to first position estimates. In 1004, parallelness is measured. For example, a uniform laser wave front is imaged through the etalon, and the resulting transmission of the wave is observed for uniformity. In 1006, it is determined whether the etalon mirrors are parallel. In response to the mirrors not being parallel, control passes to 1002. In response to the mirrors being parallel, control passes to 1008. In 1008, piezo position settings are stored. For example, the drive signals for the three piezo positioners are stored in a look up table. In 1010, it is determined whether there are more gap positions. In response to determining that there are more gap positions, control passes to 1012. In 1012, a next gap position is selected, and control passes to 1002. In response to determining that there are no more gap positions, the process ends.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system, comprising:
a semiconductor process interface;
a processor configured to:
initiate etalon free run motion;
initiate free run image frame capture via the semiconductor process interface;
determine whether a full set of band passes has been captured; and
in response to the full set of band passes having been captured, remove gaps not
on spectrum reconstruction list and construct a data cube using data from gaps not removed; and
a memory coupled to the processor and configured to provide the processor with instructions.

2. The system of claim 1, wherein the processor is further configured to receive an indication to capture data.

3. The system of claim 1, wherein the processor is further configured to stop the etalon free run motion in response to the full set of band passes having been captured.

4. The system of claim 1, wherein the processor is further configured to stop the free run image frame capture in response to the full set of band passes having been captured.

5. The system of claim 1, wherein the processor is further configured to apply a calibration in order to construct the data cube.

6. The system of claim 5, wherein the processor is further configured to apply a classifier using the data cube.

7. The system of claim 5, wherein the processor is further configured to determining a metric using the data cube.

8. The system of claim 1, wherein the etalon free run motion comprises providing a set of drive signals to piezo actuators of the etalon.

9. The system of claim 1, wherein the set of drive signals for the piezo actuators of the etalon are stored in a look up table.

10. The system of claim 9, wherein the look up table includes drive signals for three piezo actuators for a plurality of positions.

11. The system of claim 10, wherein the drive signals for the piezo actuators to position the etalon mirrors in parallel at a plurality of gaps.

12. The system of claim 1, wherein the look up table includes an offset for a position of the plurality of positions.

13. The system of claim 1, wherein the free run image frame capture is not synchronized to the etalon free run motion.

14. The system of claim 1, wherein the full set of band passes comprises bands between N and M bands.

15. The system of claim 14, wherein N is 10 and M is 200.

16. The system of claim 14, wherein the full set of band passes are taken using gaps between K and L.

17. The system of claim 16, wherein K is 100 and L is 300.

18. A method, comprising:
initiating etalon free run motion;
initiating free run image frame capture via a semiconductor process interface;
determining, using a processor, whether a full set of band passes has been captured; and
in response to the full set of band passes having been captured, removing gaps not on spectrum reconstruction list and constructing a data cube using data from gaps not removed.

19. A computer program product embodied in a non-transitory computer readable medium and comprising computer instructions for:
initiating etalon free run motion;
initiating free run image frame capture via a semiconductor process interface;
determining, using a processor, whether a full set of band passes has been captured; and
in response to the full set of band passes having been captured, removing gaps not on spectrum reconstruction list and constructing a data cube using data from gaps not removed.
